(19) United States
(12) Patent Application Publication
(10) Pub. No.: US 2026/0013067 A1
(43) Pub. Date: Jan. 8, 2026

(54) SLIDING RAIL DEVICE

(71) Applicant: FOSITEK CORPORATION, New Taipei City (TW)

(72) Inventors: Kai-Hung LIN, New Taipei City (TW); Kuan-Wei CHEN, New Taipei City (TW)

(73) Assignee: FOSITEK CORPORATION, New Taipei City (TW)

(21) Appl. No.: 18/908,239

(22) Filed: Oct. 7, 2024

(30) Foreign Application Priority Data
Jul. 5, 2024 (TW) 113125311

(51) Int. Cl. H05K 7/14

(52) U.S. Cl. CPC H05K 7/1489

(57) ABSTRACT

A sliding rail device includes an exterior frame, an outer rail, an intermediate rail, and a blocking mechanism that has a positioning member, and a blocking member having a blocking protrusion and a blocking groove. When the intermediate rail is moved relative to the outer rail, the positioning member is pushed by the blocking member to move downwardly along an inclined portion of the blocking groove, and is consequently adapted to move a linking member downwardly and adapted to drive another sliding rail device that is connected to the linking member to move synchronously in a manner where a positioning member of the another sliding rail device is moved along a blocking portion of a blocking groove to be adjacent to a blocking protrusion so as to prevent movement of the intermediate rail of the another sliding rail device relative to the outer rail of the another sliding rail device.

### CROSS-REFERENCE TO RELATED APPLICATION

This application claims priority to Taiwanese Invention Patent Application No. 113125311, filed on Jul. 5, 2024, the entire disclosure of which is incorporated by reference herein.

### FIELD

The disclosure relates to a sliding rail device, and more particularly to a sliding rail device with a blocking mechanism.

### BACKGROUND

A conventional server chassis is mounted to a server rack through a conventional sliding rail device. The conventional sliding rail device includes an outer rail fixed to the server rack, an intermediate rail movably engaged with the outer rail, and an inner rail connected to the server chassis. During maintenance or change of the server chassis, the server chassis may be pulled out from the server rack through operation of the conventional sliding rail device. However, when there are several other server chassis mounted to the server rack through other conventional sliding rail devices, and when one of the server chassis is pulled out, the corresponding conventional sliding rail device is unable to prevent another server chassis from moving outwardly on its own. Hence, there is room for improvement.

### SUMMARY

Therefore, an object of the disclosure is to provide a sliding rail device that can alleviate at least one of the drawbacks of the prior art.

According to the disclosure, the sliding rail device is adapted to be mounted to a server rack and connected to a linking member. The sliding rail device includes an exterior frame, an outer rail, an intermediate rail, and a blocking mechanism. The exterior frame is adapted to be fixed to the server rack, and has first and second ends, a frame surface, a fixing surface, and an exterior groove. The first end is opposite to the second end in a longitudinal direction. The fixing surface is opposite to the frame surface, extends between the first and second ends, and is adapted to face the server rack. The exterior groove extends through the frame surface and the fixing surface. The outer rail is disposed on the frame surface, and has a first outer rail surface, a second outer rail surface opposite to the first outer rail surface and facing the frame surface, and a connecting groove extending through the first outer rail surface and the second outer rail surface, and corresponding in position to the exterior groove. The intermediate rail is movably engaged with the outer rail, and has an intermediate rail surface facing the outer rail. The blocking mechanism has a positioning member and a blocking member. The positioning member movably extends through the exterior groove and the connecting groove, and is adapted to be fixed to the linking member. The blocking member is disposed on the intermediate rail surface, and has a blocking groove and a blocking protrusion. The blocking groove has a blocking portion and an inclined portion. The blocking portion extends in an up-down direction perpendicular to the longitudinal direction. The inclined portion extends from an upper end of the blocking portion toward the second end, and is downwardly inclined. The blocking protrusion is disposed between the blocking portion and the inclined portion. The positioning member is engaged with and movable along the blocking groove. When the intermediate rail is moved in the longitudinal direction relative to the outer rail, the positioning member is pushed by the blocking member to move downwardly along the inclined portion, and is consequently adapted to move the linking member downwardly and adapted to drive another sliding rail device that is connected to the linking member and that is identical to the sliding rail device to move synchronously in a manner where a positioning member of the another sliding rail device is moved downwardly along a blocking portion of a blocking groove of the another sliding rail device to be adjacent to a blocking protrusion of the another sliding rail device so as to prevent movement of an intermediate rail of the another sliding rail device relative to an outer rail of the another sliding rail device.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a perspective view illustrating an embodiment of a sliding rail device according to the disclosure.

FIG. 2 is a fragmentary rear view illustrating two sliding rail devices of the disclosure being connected to a linking member.

FIG. 3 is a partially exploded perspective view of the embodiment.

FIG. 4 is a fragmentary exploded perspective view of an outer rail and a blocking mechanism of the embodiment.

FIG. 5 is a fragmentary rear view of an intermediate rail and the blocking mechanism of the embodiment.

FIG. 6 is a fragmentary sectional view taken along line VI-VI in FIG. 1, and the intermediate rail and an inner rail are omitted.

FIG. 7 is a fragmentary schematic rear view of the intermediate rail and the blocking mechanism, illustrating that a positioning portion of a positioning member of the blocking mechanism is at a starting position; that is, the positioning portion is positioned at a junction between an upper end of a blocking portion of a blocking groove and an upper end of an inclined portion of the blocking groove.

FIG. 8 is a fragmentary front view of the outer rail and the blocking mechanism, illustrating that the positioning portion of the positioning member is at the starting position; that is, the positioning portion is positioned at an upper end of a connecting groove.

FIG. 9 is a fragmentary schematic rear view of the intermediate rail and the blocking mechanism, illustrating the positioning portion of the positioning member being positioned at a lower end of the inclined portion of the blocking groove.

FIG. 10 is a fragmentary front view of the outer rail and the blocking mechanism, illustrating the positioning portion of the positioning member being at a lower end of the connecting groove.

FIG. 11 is a fragmentary schematic rear view of an intermediate rail of another sliding rail device, illustrating a positioning portion of a positioning member of the another sliding rail device being adjacent to a blocking protrusion thereof.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

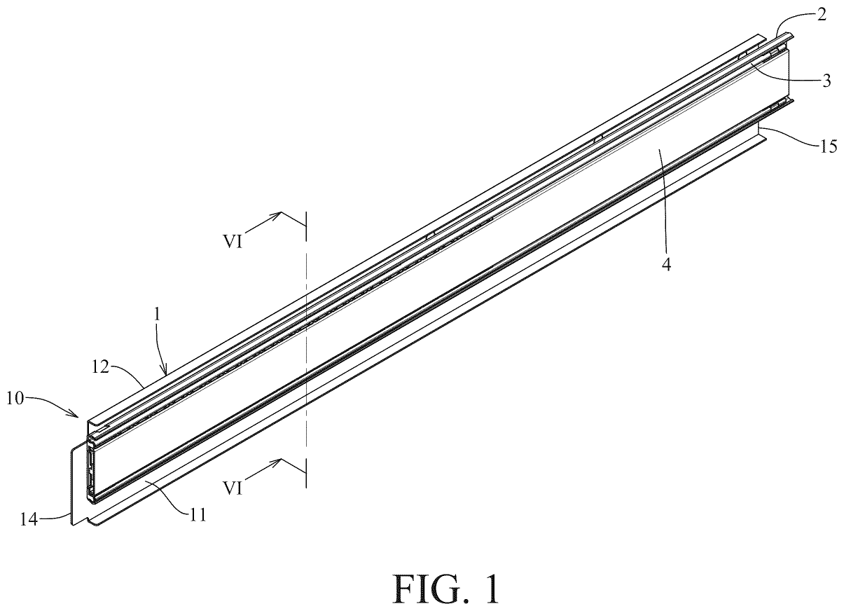

Referring to FIGS. 1 to 3, an embodiment of a sliding rail device 10 according to the disclosure is adapted to be mounted to a server rack (not shown) and connected to a linking member 6. The linking member 6 has a linking rod 61 extending in an up-down direction, and two linking plates 62 extending in a longitudinal direction perpendicular to the up-down direction. Each of the linking plates 62 is connected to the linking rod 61, and is mounted to the server rack. The linking rod 61 has two linking holes 611. The sliding rail device 10 includes an exterior frame 1, an outer rail 2, an intermediate rail 3, an inner rail 4, and a blocking mechanism 5.

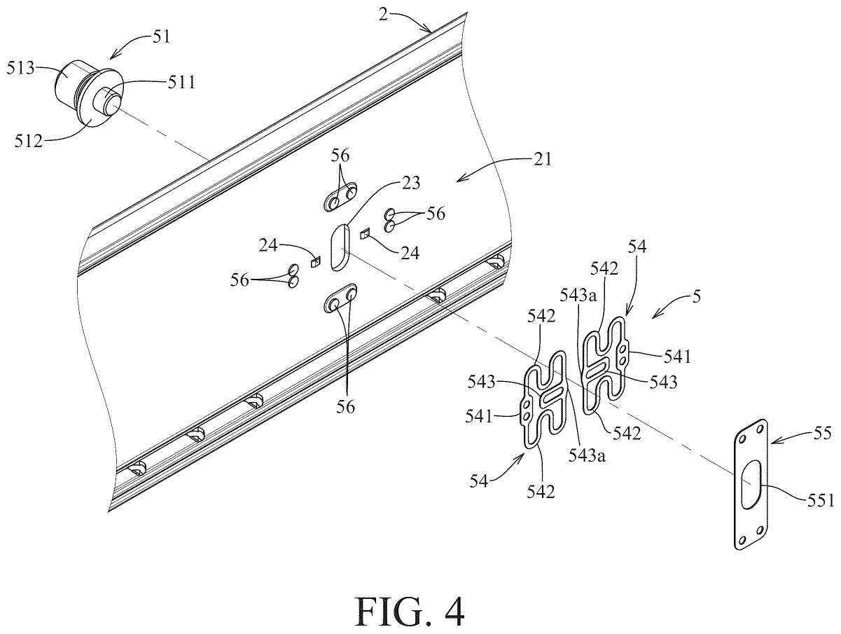

The exterior frame 1 is adapted to be fixed to the server rack, and has a frame surface 11, a fixing surface 12, an exterior groove 13, and first and second ends 14, 15. The first end 14 is opposite to the second end 15 in the longitudinal direction. The fixing surface 12 is opposite to the frame surface 11, extends between the first and second ends 14, 15, and is adapted to face the server rack. The exterior groove 13 extends through the frame surface 11 and the fixing surface 12. Referring further to FIG. 4, the outer rail 2 is disposed on the frame surface 11, and has a first outer rail surface 21, a second outer rail surface 22 opposite to the first outer rail surface 21 and facing the frame surface 11, a connecting groove 23 extending through the first outer rail surface 21 and the second outer rail surface 22, and corresponding in position to the exterior groove 13, and two engaging protrusions 24 formed on the first outer rail surface 21 and disposed respectively at opposite sides of the connecting groove 23. The intermediate rail 3 is movably engaged with the outer rail 2, and has an intermediate rail surface 31 facing the outer rail 2. The inner rail 4 is movably engaged with the intermediate rail 3, and is adapted to be connected to a server chassis (not shown).

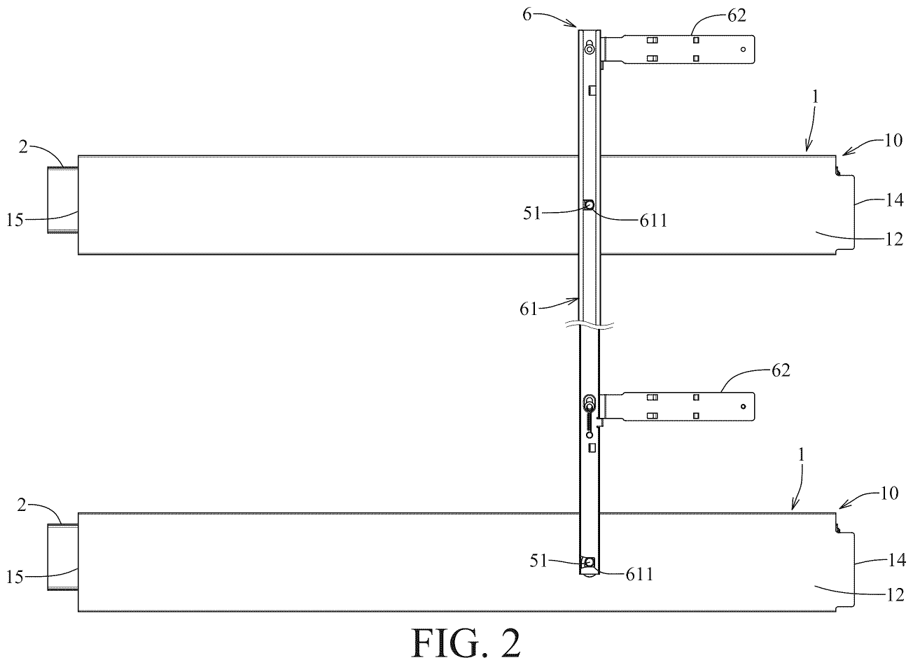

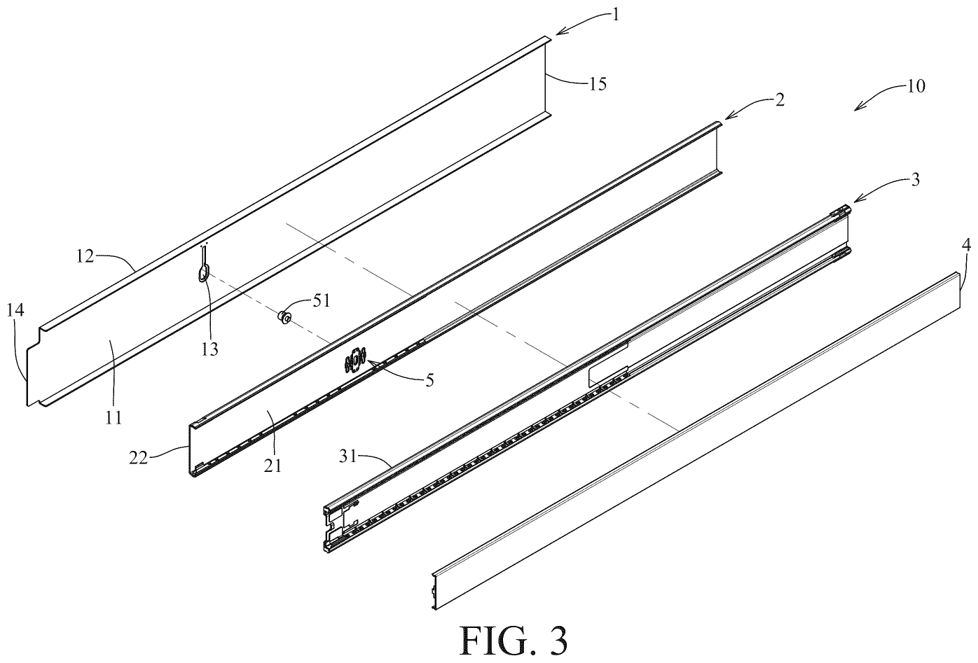

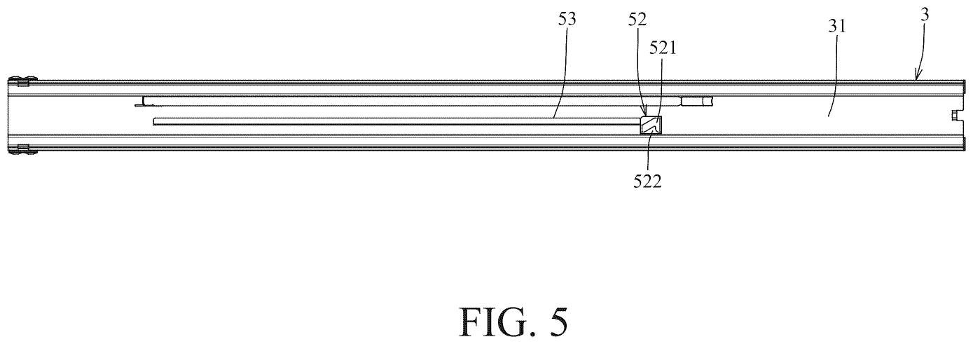

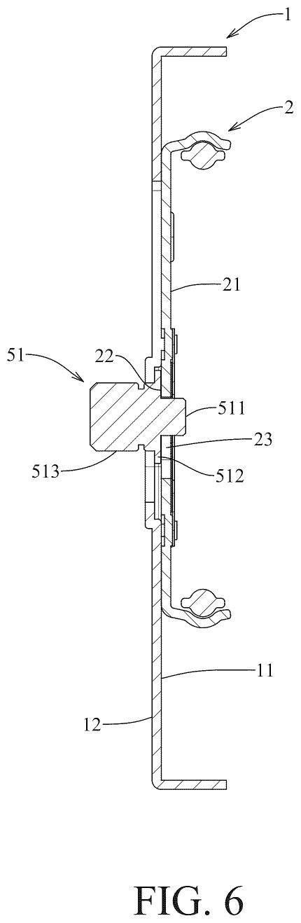

Referring to FIGS. 4 to 7, the blocking mechanism 5 has a positioning member 51 movably extending through the exterior groove 13 (see FIG. 3) and the connecting groove 23, and adapted to be fixed to the linking member 6 (see FIG. 2), a blocking member 52 disposed on the intermediate rail surface 31, a blocking strip 53 disposed on the intermediate rail surface 31, extending in the longitudinal direction, and abutting against the blocking member 52, two elastic members 54 disposed on the first outer rail surface 21, and a cover 55 connected to the first outer rail surface 21 and partially covering the elastic members 54. The positioning member 51 has a positioning portion 511 movably extending through the exterior groove 13 and the connecting groove 23, an abutting portion 512 extending from the positioning portion 511 and abutting against the second outer rail surface 22, and a joining portion 513 connected to the abutting portion 512 and adapted to be fixed to the linking member 6 via one of the linking holes 611. The positioning portion 511 and the joining portion 513 are cylinders, and the abutting portion 512 is a circular plate. A diameter of the positioning portion 511 is smaller than a diameter of the joining portion 513, and the diameter of the joining portion 513 is smaller than a diameter of the abutting portion 512. The blocking member 52 has a blocking groove 521 and a blocking protrusion 522. The positioning member 51 is engaged with and movable along the blocking groove 521. The blocking groove 521 has a blocking portion 521a that extends in the up-down direction, and an inclined portion 521b that extends from an upper end of the blocking portion 521a toward the second end 15, and that is downwardly inclined. The blocking protrusion 522 is disposed between the blocking portion 521a and the inclined portion 521b.

Each of the elastic members 54 is an elastic sheet, and has a securing portion 541 connected to the first outer rail surface 21, and having opposite ends spaced apart in the up-down direction, two curved portions 542 respectively connected to the two ends of the securing portion 541, being wave-shaped, and extending toward the connecting groove 23, and an engaging portion 543 interconnecting the curved portions 542 and formed with a limiting protrusion 543a. The engaging portion 543 of each of the elastic members 54 is in a shape of an elongated slot, and is movably engaged with a respective one of the engaging protrusions 24. The limiting protrusion 543a of each of the elastic members 54 overlaps a portion of the connecting groove 23 and abuts against the positioning portion 511. The cover 55 has a through groove 551 corresponding in position to the connecting groove 23. The positioning portion 511 of the positioning member 51 engages movably the through groove 551. In this embodiment, the blocking mechanism 5 further has a plurality of securing members 56, and the elastic members 54 and the cover 55 are connected to the first outer rail surface 21 through the securing members 56.

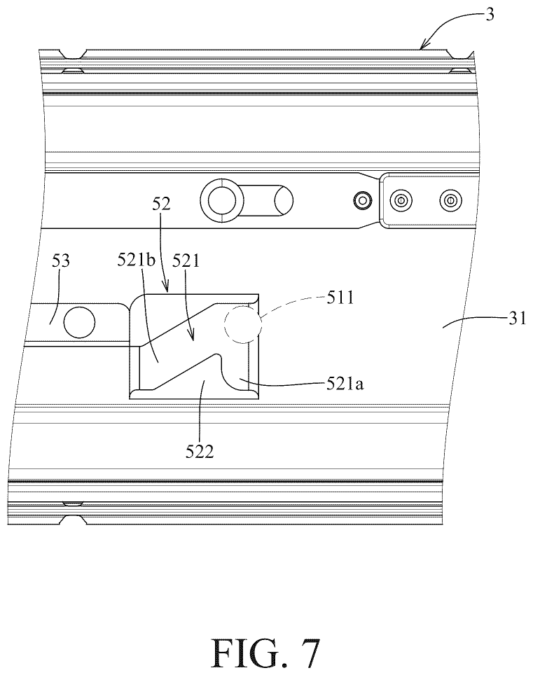

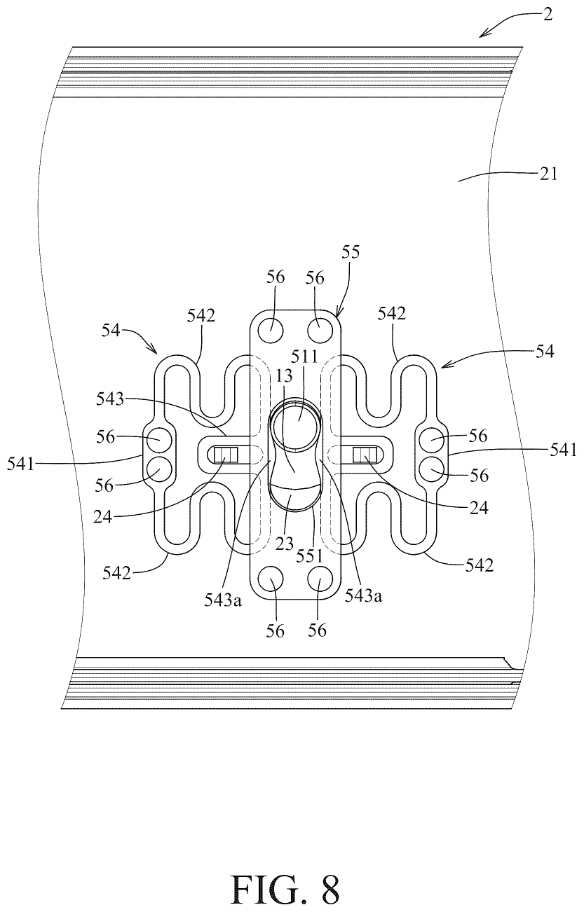

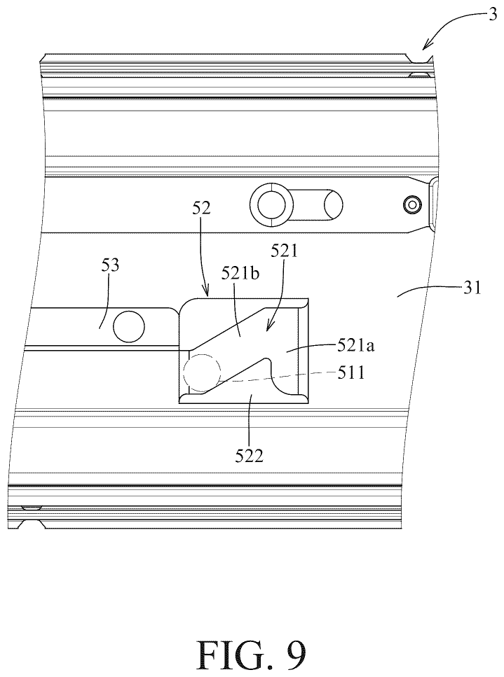

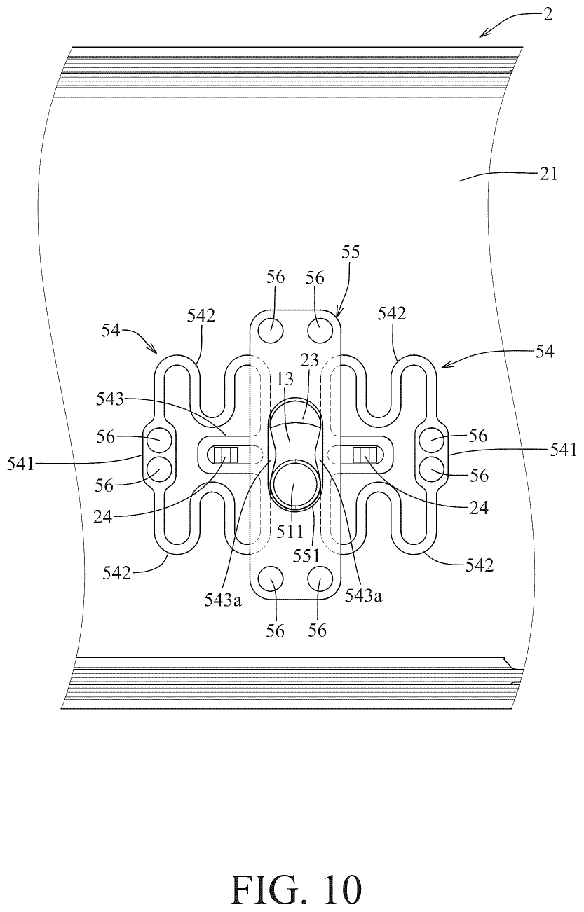

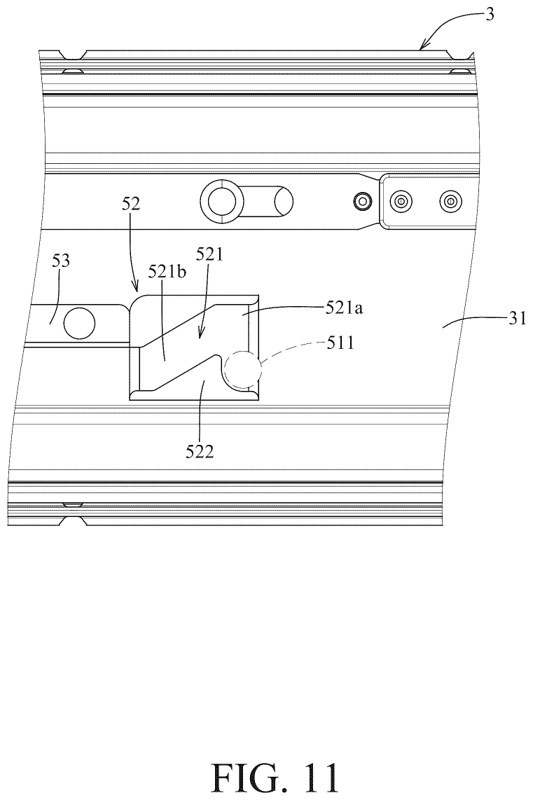

Referring to FIGS. 7 and 8, when the positioning portion 511 is at a starting position, the positioning portion 511 is disposed at a junction between an upper end of the blocking portion 521a of the blocking groove 521 and an upper end of the inclined portion 521b of the blocking groove 521 (see FIG. 7), and is also disposed at a top end of the connecting groove 23 (see FIG. 8). When the server chassis is pulled out from the server rack, the intermediate rail 3 is moved in the longitudinal direction relative to the outer rail 2, and the positioning portion 511 of the positioning member 51 is pushed by the blocking member 52 to move downwardly along the inclined portion 521b to a lower end of the inclined portion 521b (see FIG. 9) and at the same time move downwardly to a lower end of the connecting groove 23 (see FIG. 10). Since the joining portion 513 is fixed to the linking member 6, the positioning member 51 is consequently adapted to move the linking member 6 downwardly and adapted to drive another sliding rail device 10 (see FIG. 2) that is connected to the linking member 6 and that is identical to the sliding rail device 10 to move synchronously in a manner where the positioning member 51 of the another sliding rail device 10 is moved downwardly along the blocking portion 521a of the another sliding rail device 10 to be adjacent to the blocking protrusion 522 of the another sliding rail device 10 (see FIG. 11), so as to prevent movement of the intermediate rail 3 of the another sliding rail device 10 relative to the outer rail 2 of the another sliding rail device 10, thereby preventing the another sliding rail device 10 from unexpectedly moving outwards.

The limiting protrusion 543a of each of the engaging portions 543 overlaps a portion of the connecting groove 23 and abuts against the positioning portion 511, such that the positioning portion 511 is positioned at the lower end of the inclined portion 521b and is adjacent to the blocking protrusion 522 (see FIGS. 9 and 10). When the intermediate rail 3 moves in the longitudinal direction relative to the outer rail 2, the blocking strip 53 blocks the positioning portion 511 from moving upwardly (i.e., the positioning portion 511 is below the blocking strip 53), ensuring that the linking member 6 does not move upwardly, and that the blocking protrusion 522 of the another sliding rail device 10 is blocked by the positioning portion 511 of the another sliding rail device 10, so that the intermediate rail 3 of the another sliding rail device 10 will not move relative to the outer rail 2 of the another sliding rail device 10. When the server chassis is pushed back into the server rack, the positioning portion 511 of the positioning member 51 is moved towards the starting position, which drives the linking member 6 to move upwardly, thereby moving the positioning portion 511 of the another sliding rail device 10 towards the starting position, so that the positioning portion 511 of the another sliding rail device 10 no longer blocks the blocking protrusion 522 of the another sliding rail device 10. Hence, the another sliding rail device 10 will not move outwardly during use of the sliding rail device 10. It should be noted that, since the limiting protrusions 543a of the engaging portions 543 position the positioning portion 511 at the lower end of the inclined portion 521b that is adjacent to the blocking protrusion 522 when the intermediate rail 3 is pulled outwardly relative to the outer rail 2, the blocking strip 53 may be omitted in other embodiments.

In conclusion, when the intermediate rail 3 is moved in the longitudinal direction relative to the outer rail 2, the positioning member 51 is pushed by the blocking member 52 to move downwardly along the inclined portion 521b, and is consequently adapted to move the linking member 6 downwardly and adapted to drive another sliding rail device 10 that is connected to the linking member 6 and that is identical to the sliding rail device 10 to move synchronously in a manner where the positioning member 51 of the another sliding rail device 10 is moved downwardly along the blocking portion 521a of the another sliding rail device 10 to be adjacent to the blocking protrusion 522 of the another sliding rail device 10 so as to prevent movement of the intermediate rail 3 of the another sliding rail device 10 relative to the outer rail 2 of the another sliding rail device 10. Hence, the another sliding rail device 10 will not move outwardly during use of the sliding rail device 10, and an objective of the disclosure is achieved.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, the one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A sliding rail device adapted to be mounted to a server rack and connected to a linking member, said sliding rail device comprising:
an exterior frame that is adapted to be fixed to the server rack, and that has
first and second ends, said first end being opposite to said second end in a longitudinal direction;
a frame surface,
a fixing surface opposite to said frame surface, extending between said first and second ends, and adapted to face the server rack, and
an exterior groove extending through said frame surface and said fixing surface;
an outer rail that is disposed on said frame surface, and that has a first outer rail surface, a second outer rail surface opposite to said first outer rail surface and facing said frame surface, and a connecting groove extending through said first outer rail surface and said second outer rail surface, and corresponding in position to said exterior groove;
an intermediate rail that is movably engaged with said outer rail, and that has an intermediate rail surface facing said outer rail; and
a blocking mechanism that has
a positioning member movably extending through said exterior groove and said connecting groove, and adapted to be fixed to the linking member, and
a blocking member disposed on said intermediate rail surface, and having a blocking groove and a blocking protrusion, said blocking groove having
a blocking portion that extends in an up-down direction perpendicular to the longitudinal direction, and
an inclined portion that extends from an upper end of said blocking portion toward said second end, and that is downwardly inclined, said blocking protrusion being disposed between said blocking portion and said inclined portion, said positioning member being engaged with and movable along said blocking groove;
wherein, when said intermediate rail is moved in the longitudinal direction relative to said outer rail, said positioning member is pushed by said blocking member to move downwardly along said inclined portion, and is consequently adapted to move the linking member downwardly and adapted to drive another sliding rail device that is connected to the linking member and that is identical to said sliding rail device to move synchronously in a manner where a positioning member of the another sliding rail device is moved downwardly along a blocking portion of a blocking groove of the another sliding rail device to be adjacent to a blocking protrusion of the another sliding rail device so as to prevent movement of an intermediate rail of the another sliding rail device relative to an outer rail of the another sliding rail device.

2. The sliding rail device as claimed in claim 1, wherein said positioning member has a positioning portion movably extending through said exterior groove and said connecting groove, an abutting portion extending from said positioning portion and abutting against said second outer rail surface, and a joining portion connected to said abutting portion and adapted to be fixed to the linking member.

3. The sliding rail device as claimed in claim 2, wherein said positioning portion and said joining portion are cylinders, said abutting portion being a circular plate.

4. The sliding rail device as claimed in claim 2, wherein:
said blocking mechanism further includes two elastic members that are disposed on said first outer rail surface; and
each of said elastic members is formed with a limiting protrusion that overlaps a portion of said connecting groove and that abuts against said positioning portion.

5. The sliding rail device as claimed in claim 4, wherein each of said elastic members has:
a securing portion connected to said first outer rail surface, and having opposite ends spaced apart in the up-down direction;
two curved portions respectively connected to said two ends of said securing portion, being wave-shaped, and extending toward said connecting groove; and
an engaging portion interconnecting said curved portions and formed with said limiting protrusion.

6. The sliding rail device as claimed in claim 5, wherein:
said outer rail further has two engaging protrusions formed on said first outer rail surface and disposed respectively at opposite sides of said connecting groove; and
said engaging portion of each of said elastic members is in a shape of an elongated slot, and is movably engaged with a respective one of said engaging protrusions.

7. The sliding rail device as claimed in claim 4, wherein:
said blocking mechanism further includes a cover connected to said first outer rail surface and partially covering said elastic members; and
said cover has a through groove corresponding in position to said connecting groove, said positioning portion of said positioning member engaging movably said through groove.
